(19) United States
(12) Patent Application Publication
(10) Pub. No.: US 2013/0056874 A1
(43) Pub. Date: Mar. 7, 2013

(54) Protection of intermetal dielectric layers in multilevel wiring structures

(71) Applicants: Maxime Darnon, Grenoble (FR); Geraud J.-M. Dubois, San Jose, CA (US); Sebastian U. Engelmann, New York, NY (US); Teddie P. Magbitang, San Jose, CA (US); Sampath Purushothaman, Yorktown Heights, NY (US); Muthumanickam Sankarapandian, Niskayuna, NY (US); Willi Volksen, San Jose, CA (US)

(72) Inventors: Maxime Darnon, Grenoble (FR); Geraud J.-M. Dubois, San Jose, CA (US); Sebastian U. Engelmann, New York, NY (US); Teddie P. Magbitang, San Jose, CA (US); Sampath Purushothaman, Yorktown Heights, NY (US); Muthumanickam Sankarapandian, Niskayuna, NY (US); Willi Volksen, San Jose, CA (US)

(73) Assignee: INTERNATIONAL BUSINESS MACHINES CORPORATION, Armonk, NY (US)

(21) Appl. No.: 13/226,281

(22) Filed: Sep. 6, 2011

(51) Int. Cl. H01L 21/3065; H01L 23/48

(52) U.S. Cl. 257/773; 438/712; 257/E23.011; 257/E21.218

(57) ABSTRACT

A semiconductor device is accepted at a stage of its fabrication, at which stage the device includes a diffusion-barrier cap-material (DBCM) layer and an intermetal dielectric layer covering the DBCM layer. The DBCM layer is exposed and it is suitable for removal by an etching procedure in a portion of a pattern contained in the intermetal dielectric layer. A silylation treatment is performed on the semiconductor device prior to the etching procedure for removing the DBCM layer. The intermetal dielectric layer of the completed device has surfaces in contact with metal interconnects and metal vias, and it may have an excess of carbon content near at least a portion of the these surfaces.

### BACKGROUND

The present invention relates to electronic devices of very large scale integrated (VLSI) circuits. In particular, it relates to the fabrication of multilevel wiring structures.

### BRIEF SUMMARY

A semiconductor device is accepted at a stage of its fabrication, at which stage the device includes a diffusion-barrier cap-material (DBCM) layer and an intermetal dielectric layer covering the DBCM layer. The DBCM layer is exposed and it is suitable for removal by an etching procedure in a portion of a pattern contained in the intermetal dielectric layer. A silylation treatment is performed on the semiconductor device prior to the etching procedure for removing the DBCM layer. The intermetal dielectric layer of the completed device has surfaces in contact with metal interconnects and metal vias, and it may have an excess of carbon content near at least a portion of the these surfaces.

### BRIEF DESCRIPTION OF THE SEVERAL VIEWS OF THE DRAWINGS

These and other features of the present invention will become apparent from the accompanying detailed description and drawings, wherein:

FIGS. 1A-1F schematically depict cross-sectional views of processing a dual damascene interconnect structure for a semiconductor device in an embodiment of the present invention; and

FIGS. 2A-2B show cross-sectional scanning electron micrographs demonstrating the effectiveness of the disclosed processing steps for an embodiment of the present invention.

### DETAILED DESCRIPTION

A significant effort in the fabrication of VLSI chips is expended in forming the interconnections for various electrical components, for instance, transistors. In advanced circuits, multilevel wiring schemes are widely used. Multilevel wiring schemes have multiple parallel planes of interconnect lines that are connected to each other and to the electrical components by vertical vias. One multilevel wiring scheme often used in the art is the so-called dual damascene interconnect structure. A dual damascene structure is formed by filling both the wiring trenches and the via holes with metal in a single step. The wiring trenches and the via holes are formed in an intermetal dielectric layer. The trenches enclose the metal interconnects and the via holes enclose the metal vias. In a dual damascene processing sequence the desired multilevel interconnect structure is formed by repeatedly completing on the top of one another a series of steps that for each level may include: forming a dielectric layer; patterning the dielectric layer; filling the pattern with metal; and planarizing the metal.

State of the art multilevel interconnect structures typically use Cu as metal and a so called low-k intermetal dielectric layer as an insulator. The term low-k refers to the fact that the dielectric constant of the intermetal dielectric layer is lower than that of SiO₂, which is about 4. Often the low-k dielectric layers are composed of porous materials. The dielectric layer may be composed of delicate materials and may be in need of various protection schemes during the fabrication of the multilevel interconnect structure.

The embodiments of the present disclosure deal with protecting the intermetal dielectric layer in a situation where it is exposed to a particular etching procedure, which etching procedure is needed to fully open up the contact at the via holes. This etching procedure, typically involving reactive ion etch (RIE), is required to remove a diffusion-barrier cap-material (DBCM) from the bottom of via holes. It has been observed that severe roughening and pitting of the intermetal dielectric occurs during this etching procedure. This roughening is quite pronounced in porous low-k intermetal dielectrics (IMD) which are also often referred to as ultra low-k or ULK IMD's. The roughening and pitting of the intermetal dielectric in turn leads to severe line bottom topography of metal filled lines, with metal extruding out into the dielectric, especially at the bottom of the trenches. This can lead to local electric field enhancements in operation causing dielectric breakdown. In addition, any penetration of the fill metal, such as Cu, into the surrounding intermetal dielectric can cause degradation of the breakdown strength of the dielectric and compromise its electrical robustness. Embodiments of the instant disclosure teach that a silylation treatment prior to the diffusion-barrier cap-material removal step extends protection to, and mitigates the roughening and pitting of, the intermetal dielectric layer.

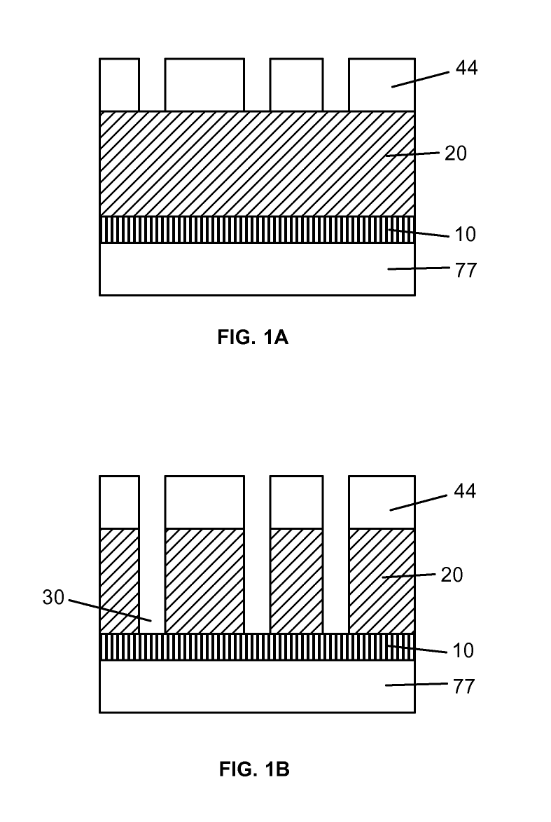

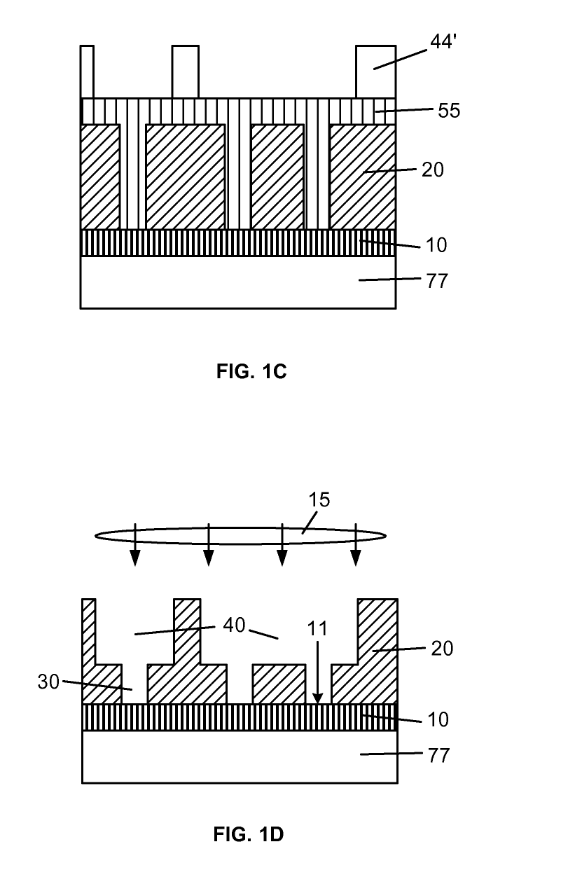

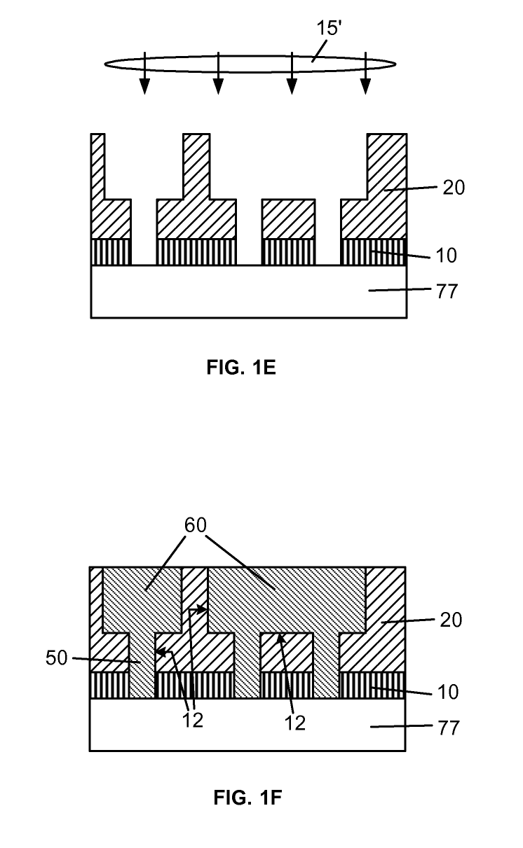

FIGS. 1A-1F schematically depict cross sectional views of processing a dual damascene interconnect structure for a semiconductor device in an embodiment of the present invention. Manufacturing dual damascene structures is established in the art. It is understood that there are a large number of steps involved in such processing, and each step may have several variations known to those skilled in the art. For embodiments of this disclosure it is understood that the whole range of known processing techniques are available for fabricating the devices, but typically only those process steps will be described that may be useful in illustrating embodiments of the present invention.

FIG. 1A shows a semiconductor device in a state of fabrication during dual damascene interconnection processing. The bottommost layer 77 symbolically indicates all lower levels of the device. Such levels may include electronic devices, for instance transistors, and also may include already completed wiring levels of the multilevel wiring structure that is being fabricated. Laterally, the figures illustratively show what may be only a small fraction of the VLSI semiconductor device, with the left and right boundary lines not intending to represent physical boundaries. The figures show only a few vias and wire trenches, while in such VLSI semiconductor device processing in reality one may deal with thousands or even millions of such elements.

Covering the lower levels 77 there is a diffusion-barrier cap-material (DBCM) layer 10. Such layers are known in the art serving the purpose of preventing various materials, for instance Cu, from diffusing from the layers that are being processed into the already completed lower levels 77, as well as, into any upper levels which are subsequently added. Typical materials that compose DBCM layers may be, for example, silicon nitride, silicon carbide, silicon carbonitride and combinations thereof and their thickness may be between 5 nm to 100 nm. This DBCM layer is the one that at the bottom of the via holes will have to be etched away in order to allow electrical contacts in between the to be added upper wiring level and previously fabricated lower wiring level, or devices. The intermetal dielectric layer 20 covers the DBCM layer 10. In representative embodiments of the disclosure the intermetal dielectric material is a low-k dielectric. Such materials may include, without limitation, porous silicon oxide and porous organosilicates such as silsesquioxanes, oxycarbosilanes and the like. These dielectrics can be deposited by using processes such as spin coating, chemical vapor deposition (CVD), plasma enhanced chemical vapor deposition (PECVD) followed by optional thermal and or UV exposure assisted curing steps. The desire for such materials stems from the fact that it is advantageous for the medium surrounding the wires to have the lowest possible dielectric constant. Lowering this dielectric constant decreases the capacitive load on the electrical devices.

The intermetal dielectric layer 20 has to be patterned for imbedding the metal interconnects and vias. A patterned photoresist layer 44 is produced on top of the intermetal dielectric layer 20, which photoresist is then used to pattern the dielectric layer 20. FIG. 1A shows the photoresist layer 44 containing the pattern for the via holes which pattern will be transferred into the dielectric layer 20.

The layers shown in FIG. 1A, and the processes forming them, are known in the art. As already stated in regard of illustrating the embodiments, in actual processing at the stage shown in FIG. 1A there may be many more layers than those shown in the figure. Such layers may be various antireflection coatings, optional hard mask layers comprising silicon oxides such as TEOS, organosilicate layers such as OMCTS (PECVD deposited octamethylcyclotetrasiloxane films), metallic hard masks such as titanium nitride and suitable combinations thereof. These optional hard mask layers may be employed between the IMD layer 20 and the photoresist layer 44 to provide a better lithographic process latitude and to allow rework and removal of the photoresist layer 44 without exposing the IMD layer to such treatments. All such are known in the art, and displaying them would only crowd the figures, since they may be of no special interest in regard to embodiments of the present invention.

FIG. 1B shows a later stage in the processing of the dual damascene interconnect structure. The via pattern from the photoresist layer 44 has been transferred into the intermetal dielectric layer 20, thereby opening up the via holes 30. The via holes 30 typically may penetrate down to the DBCM layer 10 which is usually between 5 nm and 100 nm thick.

FIG. 1C shows a later stage in the processing of the dual damascene interconnect structure. A planarizing layer 55, typically an organic material, has been blanket applied over the structure to facilitate further patterning. The figure also shows a patterning layer, which may again be a photoresist layer 44′, which now holds the pattern for the trenches of the interconnecting wires. As mentioned earlier, additional layers such as an antireflective coating layer and a hard mask layer can be employed between the photoresist layer 44′ and the planarizing layer 55. A silicon containing hard mask layer is especially useful in enabling high fidelity transfer of the pattern in the photoresist layer 44′ into the planarizing layer 55 which then acts as the mask to transfer the said pattern into the underlying IMD layer 20 using RIE processes, often employed in the art.

FIG. 1D shows a structure which is a later stage in the processing of the dual damascene interconnect structure, and it also shows a processing step 15. The interconnect structure is at the fabrication stage where the intermetal dielectric layer 20 already contains the complete pattern of the via holes 30 and of the wiring trenches 40. In a portion of the pattern, namely at the bottom of the via holes 30, the DBCM layer 10 is exposed 11 and is suitable for removal by an etching procedure. The removal of the exposed portion 11 of the DBCM layer 10 assures electrical connectivity to the lower level 77.

The starting point of representative embodiments of the present invention is the structure illustratively shown in FIG. 1D. The multilevel wiring structure is accepted at this stage for further processing as per the embodiments of the present invention. The term of accepting is intended to be inclusive of any possible manner by which one may arrive at this stage in the fabrication of the structure. Typically, the processing may have just reached this stage of fabrication, as depicted schematically in FIGS. 1A to 1C, or samples may have been supplied in this stage of fabrication, in any manner from any source, in order to be further processed.

The symbolically shown processing step 15 of FIG. 1D may be a novel step in the embodiments of the instant invention. The processing step 15 represents the performing of a silylation treatment on the semiconductor device prior to the etching procedure for removing the exposed portion 11 of the DBCM layer 10, at the bottom of the via holes 30.

Silylation treatment as such has already been presented in the art, for instance it is taught in detail in US patent publication No.: 20090075472A1 published Mar. 19, 2009, or in U.S. Pat. No. 7,179,758 to Chakrapani et al. Hence, here only its salient features will be briefly presented. There are a large number of silylation agents with a general chemical formula of Xₙ—Si—Rₘ, where n+m=4 or (XₙRₘSi)₂Y where n+m=3 and X is a reactive functionality such as chloride, amine, alkoxy and the like and R is hydrogen or an organic functionality such as either an alkyl group (e.g., methyl, ethyl, isopropyl, vinyl and the like) or aromatic (e.g. phenyl and the like) and Y is a carbon-bridging group such as —(CH₂)ₙ— where n=1-3 and the like. Some examples of these agents include but are not limited to trichlorosilane, trimethoxy silane, bis(dimethylamino)dimethylsilane, phenyl silane, bis(dimethylaminodimethylsilyl)ethane and the like. The reactive functionality groups preferentially react with, and cap off, the hydroxyl functionalities often generated due to process exposure damage to the low-k organosilicate IMD's. These silylation agents may be applied to the structure in a variety of ways, hence in FIG. 1D a symbolic representation 15 is given, indicating a wide range of possibilities to deliver the silylation treatment. In representative embodiments of the present disclosure these agents, without limitation, may be applied by liquid or solution form, dissolved and delivered in a supercritical fluid medium such as supercritical carbon dioxide, or in a vapor form of the agent. But, any silylation agent, and any delivery method is included within the scope of the embodiments of the present invention

The novelty in the embodiments of the present invention is not in the technique of silylation itself, but in using silylation at this stage of the fabrication in order to preempt damage that the etching, typically a plasma enhanced RIE, of the DBCM layer 10 causes to the exposed surfaces of the intermetal dielectric layer 20. The ability of a silylation treatment 15 to mitigate the effects of the DBCM layer 10 opening etch, which etch has significant ion energy, and has fluorine (F) rich components, is an unexpected result. In particular, the DBCM layer which is usually a dense and difficult etch barrier layer requires etch conditions that lie above the pitting and roughening damage threshold of the low-k material. Typical etch conditions employ etch gases such as argon, oxygen, nitrogen, any fluorohydrocarbon type CₓH_{y}F_{z} gas (x=1-5, y=1-3, z=1-8) and combinations thereof. As a result of the etch gas chemistries employed in the process and the high ion energy required to etch the DBCM layer (typically >100 eV), very poor selectivity of etching the DBCM layer 10 relative to the intermetal dielectric layer 20 may result and furthermore severe damage due to oxygen and fluorine penetration of the intermetal dielectric layer 20 may result.

FIG. 1E shows a structure, which is a later stage in the processing of the dual damascene interconnect structure and a processing step 15′. The depicted stage in the fabrication is one that follows the etching and removal of the DBCM layer 10 from the bottom of the via holes. The symbolically shown processing step 15′ of FIG. 1E is an additional silylation treatment 15′, which is subsequent to the removal of the DBCM layer 10 from the bottom of the via holes. This additional silylation treatment 15′ is optional. However, it has been found that this additional silylation treatment 15′ in many instances further improves the quality of the intermetal dielectric layer 20. The priming of the indicator number 15 for the additional silylation treatment is meant to indicate that the additional silylation treatment 15′ is not necessarily the same as the silylation treatment 15 that preceded the removal of the DBCM layer 10, and one can opt to use the same or a different silylation agent and or delivery method to facilitate the silylation treatment 15′ as compared to treatment 15.

FIG. 1F shows a structure, which is a later stage in the processing of the dual damascene interconnect structure. A metal layer has been formed over the structure of FIG. 1E, and then planarized, resulting in this metal constituting now the vias 50 and the wiring 60 in the discussed level of the multilevel interconnect structure. If one were to continue with additional levels, the next step may be one of forming an additional DBCM layer over the structure as shown in FIG. 1F.

As one knowledgeable in the art would notice, the processing steps shown in FIGS. 1A-1F followed a so called via first approach in the fabrication of this particular wiring level. However, this should not be interpreted in a restrictive manner. One may have instead shown a sequence of a so-called trench first approach in illustrating the embodiments of the invention. In both approaches, via first and trench first, one eventually arrives to the state shown in FIG. 1D, where the structure is ready for etching the DBCM layer 10 from the bottom of the via holes 30, and the intermetal dielectric layer 20 is exposed. Thus, the silylation treatment 15 at this particular point in the process is equally applicable to both the via first and the trench first approaches.

As shown in FIG. 1F, the low-k dielectric layer 20 is enclosing a network of metal interconnects 60 and metal vias 50, and the dielectric layer 20 has surfaces 12 in contact with the metal interconnects 60 and the metal vias 50. The silylation treatment 15, as shown in FIG. 1D, may have reacted with the low-k dielectric layer 20 as it existed after the stripping of the patterning materials. The silylation treatment 15 reactions may have produced an enriched carbon content region on the low-k dielectric layer 20 surfaces 12, which region then protected the underlying material during the DBCM layer 10 etching. Consequently, the low-k dielectric layer 20 carbon content distribution may be an indicator of the silylation treatment 15.

The low-k dielectric layer 20 has an average carbon content depending on its exact material composition. It is known in the art that due to the exposures to the various etching steps required to generate the dual damascene trench and via structures, the carbon content can be depleted in the exposed regions of the low k IMD. This carbon depletion may be non-uniform over this surface depending upon the plasma gas chemistries and the energetics of the ion and neutral species generated in the etching plasmas. Such non-uniformities can be further aggravated by the presence of porosity as in the case of the ultra low-k films. When a low-k or ultra low-k IMD with non-uniform carbon content is exposed to the aggressive plasma RIE process required to remove the DBCM layer, differential etching of the regions with different carbon contents can occur leading to pitting and roughening of the IMD surfaces. Silylation treatment performed before the DBCM layer removal by RIE could restore the carbon depletion such that the carbon content in the exposed IMD regions is more homogeneous and higher than the depleted condition At the same time, in specific locations it may have an excess carbon content in comparison to the average carbon content. This restoration may result in excess carbon content in the low-k dielectric layer 20 near at least a portion of its surfaces 12 that contact the metal wires 60 and vias 50. Such excess of carbon content may be indicative that a silylation treatment 15 has been applied prior to the DBCM layer 10 etch.

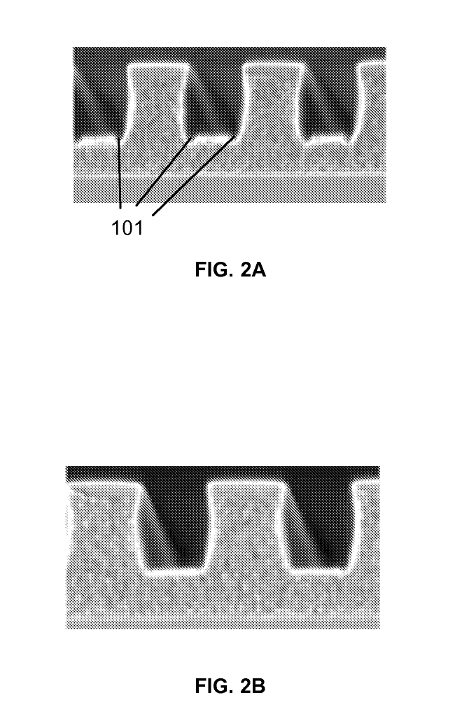

FIGS. 2A-2B show cross-sectional scanning electron micrographs demonstrating the effectiveness of the disclosed processing steps for embodiments of the present invention. Both figures show etched line trenches in an ultra low-k dielectric material, a porous oxycarbosilane with a dielectric constant of about 2.0 and about 50% porosity, which has been exposed to the type of RIE etching used for removing the DBCM layer from the bottom of the vias. FIG. 2A shows the state of the ultra low-k dielectric when no silylation treatment was applied prior to the DBCM RIE. Damage in the forms of pits 101 is clearly visible. The ultra low-k dielectric shown in FIG. 2B did receive the silylation treatment prior to the DBCM RIE, and shows no discernible damage of any form. The difference of the condition of the low-k dielectric between the two figures demonstrates the protective effect of the silylation treatment, as taught by the embodiments of the present invention.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

In addition, any specified material or any specified dimension of any structure described herein is by way of example only. Furthermore, as will be understood by those skilled in the art, the structures described herein may be made or used in the same way regardless of their position and orientation. Accordingly, it is to be understood that terms and phrases such as “under,” “upper”, “side,” “over”, “underneath” etc., as used herein refer to relative location and orientation of various portions of the structures with respect to one another and are not intended to suggest that any particular absolute orientation with respect to external objects is necessary or required.

The foregoing specification also describes processing steps. It is understood that the sequence of such steps may vary in different embodiments from the order that they were detailed in the foregoing specification. Consequently, the ordering of processing steps in the claims, unless specifically stated, for instance, by such adjectives as “prior”, “before”, “ensuing”, “after”, “subsequent”, etc., does not imply or necessitate a fixed order of step sequence.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature, or element, of any or all the claims.

Many modifications and variations of the present invention are possible in light of the above teachings, and could be apparent for those skilled in the art. The scope of the invention is defined by the appended claims.

1. A method, comprising:
accepting a semiconductor device in a state of fabrication, wherein in said state of fabrication said semiconductor device comprises a diffusion-barrier cap-material (DBCM) layer and an intermetal dielectric layer covering said DBCM layer, wherein said intermetal dielectric layer contains a pattern, wherein in a portion of said pattern said DBCM layer is exposed and is suitable for removal by an etching procedure; and
performing a silylation treatment on said semiconductor device prior to said etching procedure.

2. The method of claim 1, wherein said method is characterized as being processing of a dual damascene interconnect structure.

3. The method of claim 1, wherein said intermetal dielectric layer is selected to be a low-k dielectric layer.

4. The method of claim 1, wherein said method is selected to be a via first approach.

5. The method of claim 1, wherein said method is selected to be a trench first approach.

6. The method of claim 1, wherein said method further comprises performing said etching procedure.

7. The method of claim 6, wherein said etching procedure is selected to be a reactive ion etching (RIE) procedure.

8. The method of claim 7, wherein said method further comprises an additional silylation treatment subsequent to said RIE procedure.

9. A structure, comprising:
a low-k dielectric having a carbon content, wherein said low-k dielectric is enclosing a network of metal interconnects and metal vias and has surfaces in contact with said metal interconnects and said metal vias;
an excess of said carbon content near at least a portion of said surfaces compared to an average of said carbon content of said low-k dielectric; and
wherein said structure is characterized as being an interconnect structure for a semiconductor device.
